(19) United States
(12) Patent Application Publication
(10) Pub. No.: US 2026/0204297 A1
(43) Pub. Date: Jul. 16, 2026

(54) MEMORY CELL HAVING HIGH MANUFACTURING CAPABILITY

(71) Applicant: TAIWAN SEMICONDUCTOR MANUFACTURING COMPANY, LTD., Hsinchu (TW)

(72) Inventor: Jhon Jhy LIAW, Hsinchu (TW)

(73) Assignee: TAIWAN SEMICONDUCTOR MANUFACTURING COMPANY, LTD., Hsinchu (TW)

(21) Appl. No.: 19/018,487

(22) Filed: Jan. 13, 2025

(51) Int. Cl. G11C 5/06; G11C 11/417; H10B 10/00

(52) U.S. Cl. CPC G11C 5/063; G11C 11/417; H10B 10/125

(57) ABSTRACT

For a memory cell: a first storage portion, a second storage portion and a match portion are located in a transistor layer (TL); four bit line segments and two search line segments are located in a first front metal layer (FML) above the TL; a word line segment and a match line segment are located in a second FML above the first FML; a VDD line segment and a VSS line segment are located in a back metal layer below the TL; the first storage portion is electrically connected to two of the bit line segments, and to the word, VDD and VSS line segments; the second storage portion is electrically connected to the other two of the bit line segments; and the match portion is disposed between the first and second storage portions, and is electrically connected to the search and match line segments.

### BACKGROUND

The semiconductor integrated circuit (IC) industry has, over the decades, experienced tremendous advancements and is still undergoing vigorous development. With dramatic advances in technology, the industry pays much attention to the development of memory cells having high manufacturing capability.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram illustrating a memory device in accordance with some embodiments.

FIG. 2 is a circuit diagram illustrating a memory cell in accordance with some embodiments.

FIGS. 3 and 4 are schematic diagrams illustrating relative positions (in an X direction and a Y direction) of various components of a memory cell in accordance with some embodiments.

FIGS. 5 to 9 are schematic sectional views of the memory cell respectively taken along lines C1-C1, C2-C2, C3-C3, C4-C4 and C5-C5 of FIGS. 3 and 4 in accordance with some embodiments.

FIG. 10 is a schematic diagram illustrating relative positions (in an X direction and a Y direction) of various components of a memory cell in accordance with some embodiments.

FIG. 11 is a schematic diagram illustrating relative positions (in an X direction and a Y direction) of various components of a memory cell in accordance with some embodiments.

FIG. 12 is a schematic diagram illustrating relative positions (in an X direction and a Y direction) of various components of a memory cell in accordance with some embodiments.

FIG. 13 is a block diagram illustrating a memory device in accordance with some embodiments.

FIG. 14 is a circuit diagram illustrating a memory cell in accordance with some embodiments.

FIG. 15 is a schematic diagram illustrating relative positions (in an X direction and a Y direction) of various components of a memory cell in accordance with some embodiments.

FIG. 16 is a schematic diagram illustrating relative positions (in an X direction and a Y direction) of various components of a memory cell in accordance with some embodiments.

FIG. 17 is a schematic sectional view of a memory device in accordance with some embodiments.

FIG. 18 is a top view of a bump pad layer in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly.

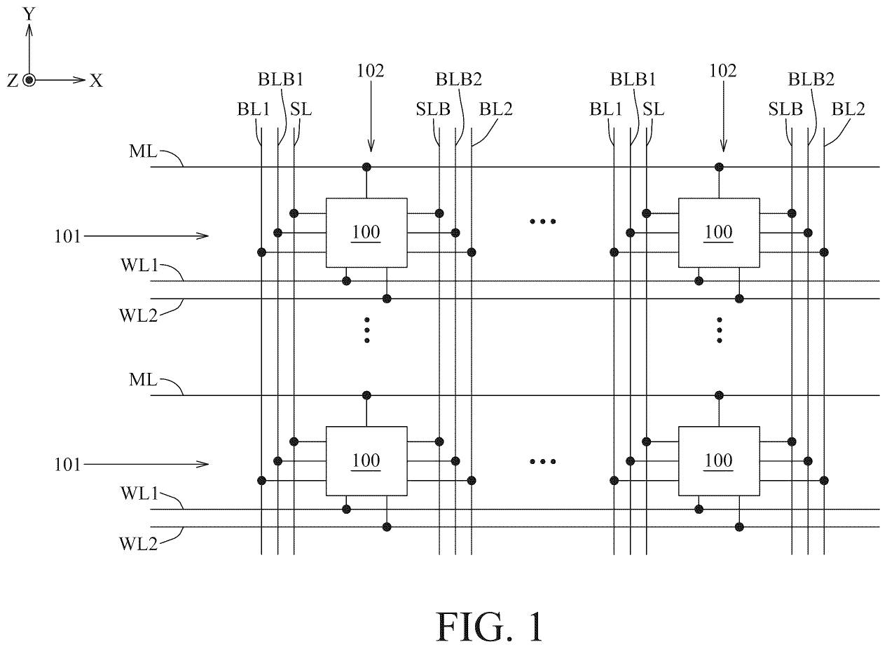

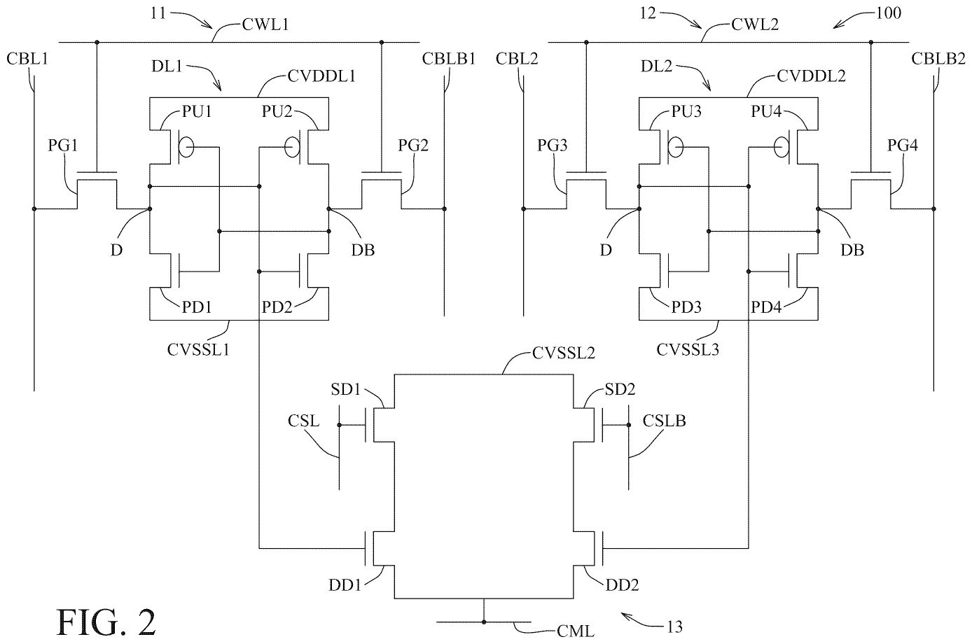

FIG. 1 is a block diagram illustrating a memory device in accordance with some embodiments. FIG. 2 is a circuit diagram illustrating a memory cell in accordance with some embodiments. Referring to FIGS. 1 and 2, the memory device includes a plurality of memory cells 100. The memory cells 100 are arranged in a matrix that has a plurality of columns 102 aligned in a first direction (e.g., an X direction transverse to a Z direction, where the Z direction points from bottom to top of the memory device) and a plurality of rows 101 aligned in a second direction (e.g., a Y direction transverse to the X direction and the Z direction).

Each of the memory cells 100 is a ternary content addressable memory (TCAM) cell, and includes a first storage portion 11, a second storage portion 12, a match portion 13, a first non-inverting bit line segment (CBL1), a first inverting bit line segment (CBLB1), a second non-inverting bit line segment (CBL2), a second inverting bit line segment (CBLB2), a non-inverting search line segment (CSL), an inverting search line segment (CSLB), a first word line segment (CWL1), a second word line segment (CWL2), a match line segment (CML), a first VDD line segment (CVDDL1), a second VDD line segment (CVDDL2), a first VSS line segment (CVSSL1), a second VSS line segment (CVSSL2), a third VSS line segment (CVSSL3) and a fourth VSS line segment (not shown).

With respect to each of the memory cells 100, the first storage portion 11 is a single-port static random access memory (SRAM) cell, and includes a first pull-up transistor (PU1), a second pull-up transistor (PU2), a first pull-down transistor (PD1), a second pull-down transistor (PD2), a first pass-gate transistor (PG1) and a second pass-gate transistor (PG2). Each of the transistors (PU1, PU2, PD1, PD2, PG1, PG2) includes a gate electrode, a first source/drain region and a second source/drain region. The first source/drain region of the first pull-up transistor (PU1), the first source/drain region of the first pull-down transistor (PD1), the first source/drain region of the first pass-gate transistor (PG1), the gate electrode of the second pull-up transistor (PU2) and the gate electrode of the second pull-down transistor (PD2) are electrically connected to each other. The first source/drain region of the second pull-up transistor (PU2), the first source/drain region of the second pull-down transistor (PD2), the first source/drain region of the second pass-gate transistor (PG2), the gate electrode of the first pull-up transistor (PU1) and the gate electrode of the first pull-down transistor (PD1) are electrically connected to each other. The second source/drain region of the first pull-up transistor (PU1) and the second source/drain region of the second pull-up transistor (PU2) are electrically connected to the first VDD line segment (CVDDL1). The second source/drain region of the first pull-down transistor (PD1) and the second source/drain region of the second pull-down transistor (PD2) are electrically connected to the first VSS line segment (CVSSL1). The gate electrode of the first pass-gate transistor (PG1) and the gate electrode of the second pass-gate transistor (PG2) are electrically connected to the first word line segment (CWL1). The second source/drain region of the first pass-gate transistor (PG1) is electrically connected to the first non-inverting bit line segment (CBL1). The second source/drain region of the second pass-gate transistor (PG2) is electrically connected to the first inverting bit line segment (CBLB1). Therefore, the first pull-up transistor (PU1) and the first pull-down transistor (PD1) cooperatively form a first inverter. The second pull-up transistor (PU2) and the second pull-down transistor (PD2) cooperatively form a second inverter. The first inverter and the second inverter are cross-coupled so as to form a first data latch (DL1) for storing data. The first data latch (DL1) includes a non-inverting data node (D) that is electrically connected to the first source/drain region of the first pass-gate transistor (PG1), and an inverting data node (DB) that is electrically connected to the first source/drain region of the second pass-gate transistor (PG2). When the first pass-gate transistor (PG1) and the second pass-gate transistor (PG2) conduct, a write operation is allowed to be performed on the first data latch (DL1).

Similarly, with respect to each of the memory cells 100, the second storage portion 12 is a single-port SRAM cell, and includes a third pull-up transistor (PU3), a fourth pull-up transistor (PU4), a third pull-down transistor (PD3), a fourth pull-down transistor (PD4), a third pass-gate transistor (PG3) and a fourth pass-gate transistor (PG4). Each of the transistors (PU3, PU4, PD3, PD4, PG3, PG4) includes a gate electrode, a first source/drain region and a second source/drain region. The first source/drain region of the third pull-up transistor (PU3), the first source/drain region of the third pull-down transistor (PD3), the first source/drain region of the third pass-gate transistor (PG3), the gate electrode of the fourth pull-up transistor (PU4) and the gate electrode of the fourth pull-down transistor (PD4) are electrically connected to each other. The first source/drain region of the fourth pull-up transistor (PU4), the first source/drain region of the fourth pull-down transistor (PD4), the first source/drain region of the fourth pass-gate transistor (PG4), the gate electrode of the third pull-up transistor (PU3) and the gate electrode of the third pull-down transistor (PD3) are electrically connected to each other. The second source/drain region of the third pull-up transistor (PU3) and the second source/drain region of the fourth pull-up transistor (PU4) are electrically connected to the second VDD line segment (CVDDL2). The second source/drain region of the third pull-down transistor (PD3) and the second source/drain region of the fourth pull-down transistor (PD4) are electrically connected to the third VSS line segment (CVSSL3). The gate electrode of the third pass-gate transistor (PG3) and the gate electrode of the fourth pass-gate transistor (PG4) are electrically connected to the second word line segment (CWL2). The second source/drain region of the third pass-gate transistor (PG3) is electrically connected to the second non-inverting bit line segment (CBL2). The second source/drain region of the fourth pass-gate transistor (PG4) is electrically connected to the second inverting bit line segment (CBLB2). Therefore, the third pull-up transistor (PU3) and the third pull-down transistor (PD3) cooperatively form a third inverter. The fourth pull-up transistor (PU4) and the fourth pull-down transistor (PD4) cooperatively form a fourth inverter. The third inverter and the fourth inverter are cross-coupled so as to form a second data latch (DL2) for storing data. The second data latch (DL2) includes a non-inverting data node (D) that is electrically connected to the first source/drain region of the third pass-gate transistor (PG3), and an inverting data node (DB) that is electrically connected to the first source/drain region of the fourth pass-gate transistor (PG4). When the third pass-gate transistor (PG3) and the fourth pass-gate transistor (PG4) conduct, a write operation is allowed to be performed on the second data latch (DL2).

With respect to each of the memory cells 100, the match portion 13 includes a first search transistor (SD1), a second search transistor (SD2), a first data transistor (DD1) and a second data transistor (DD2). The first search transistor (SD1) includes a gate electrode that is electrically connected to the non-inverting search line segment (CSL), a first source/drain region, and a second source/drain region that is electrically connected to the second VSS line segment (CVSSL2). The second search transistor (SD2) includes a gate electrode that is electrically connected to the inverting search line segment (CSLB), a first source/drain region, and a second source/drain region that is electrically connected to the second VSS line segment (CVSSL2). The first data transistor (DD1) includes a gate electrode that is electrically connected to the non-inverting data node (D) of the first data latch (DL1), a first source/drain region that is electrically connected to the first source/drain region of the first search transistor (SD1), and a second source/drain region that is electrically connected to the match line segment (CML). The second data transistor (DD2) includes a gate electrode that is electrically connected to the non-inverting data node (D) of the second data latch (DL2), a first source/drain region that is electrically connected to the first source/drain region of the second search transistor (SD2), and a second source/drain region that is electrically connected to the match line segment (CML). The match portion 13 is configured to detect a match between data stored in the first data latch (DL1) and the second data latch (DL2), and data inputted to the match portion 13 through the non-inverting search line segment (CSL) and the inverting search line segment (CSLB).

With respect to each of the memory cells 100, the fourth VSS line segment is electrically connected to the first VSS line segment (CVSSL1), the second VSS line segment (CVSSL2) and the third VSS line segment (CVSSL3).

With respect to each of the rows 101, the first word line segments (CWL1) of the memory cells 100 in the row 101 are connected in series so as to form a first word line (WL1) that corresponds to the row 101 and that extends in the X direction, the second word line segments (CWL2) of the memory cells 100 in the row 101 are connected in series so as to form a second word line (WL2) that corresponds to the row 101 and that extends in the X direction, and the match line segments (CML) of the memory cells 100 in the row 101 are connected in series so as to form a match line (ML) that corresponds to the row 101 and that extends in the X direction. With respect to each of the columns 102, the first non-inverting bit line segments (CBL1) of the memory cells 100 in the column 102 are connected in series so as to form a first non-inverting bit line (BL1) that corresponds to the column 102 and that extends in the Y direction, the first inverting bit line segments (CBLB1) of the memory cells 100 in the column 102 are connected in series so as to form a first inverting bit line (BLB1) that corresponds to the column 102 and that extends in the Y direction, the second non-inverting bit line segments (CBL2) of the memory cells 100 in the column 102 are connected in series so as to form a second non-inverting bit line (BL2) that corresponds to the column 102 and that extends in the Y direction, the second inverting bit line segments (CBLB2) of the memory cells 100 in the column 102 are connected in series so as to form a second inverting bit line (BLB2) that corresponds to the column 102 and that extends in the Y direction, the non-inverting search line segments (CSL) of the memory cells 100 in the column 102 are connected in series so as to form a non-inverting search line (SL) that corresponds to the column 102 and that extends in the Y direction, and the inverting search line segments (CSLB) of the memory cells 100 in the column 102 are connected in series so as to form an inverting search line (SLB) that corresponds to the column 102 and that extends in the Y direction.

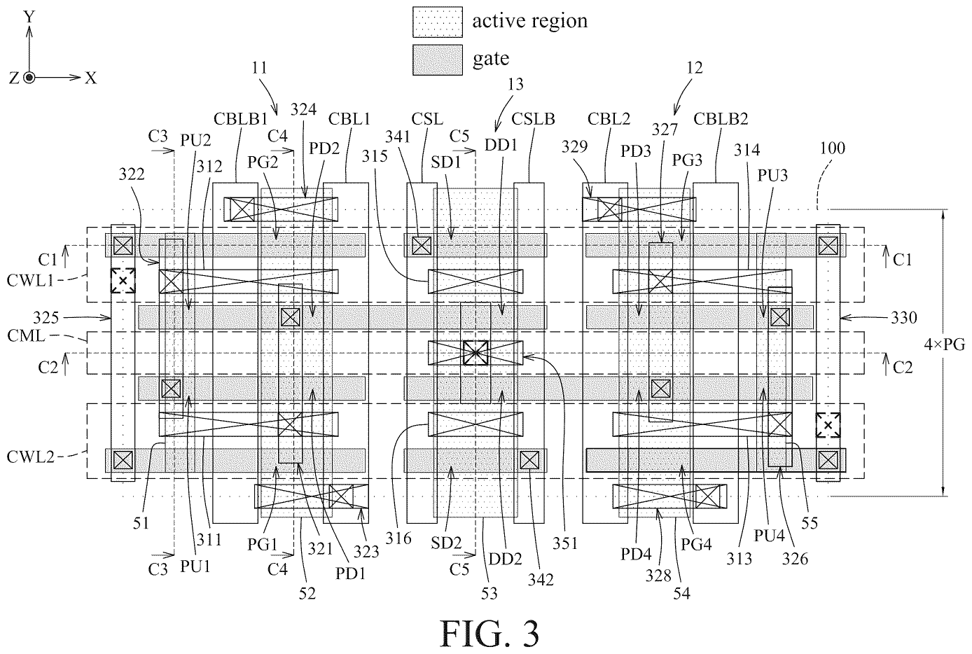

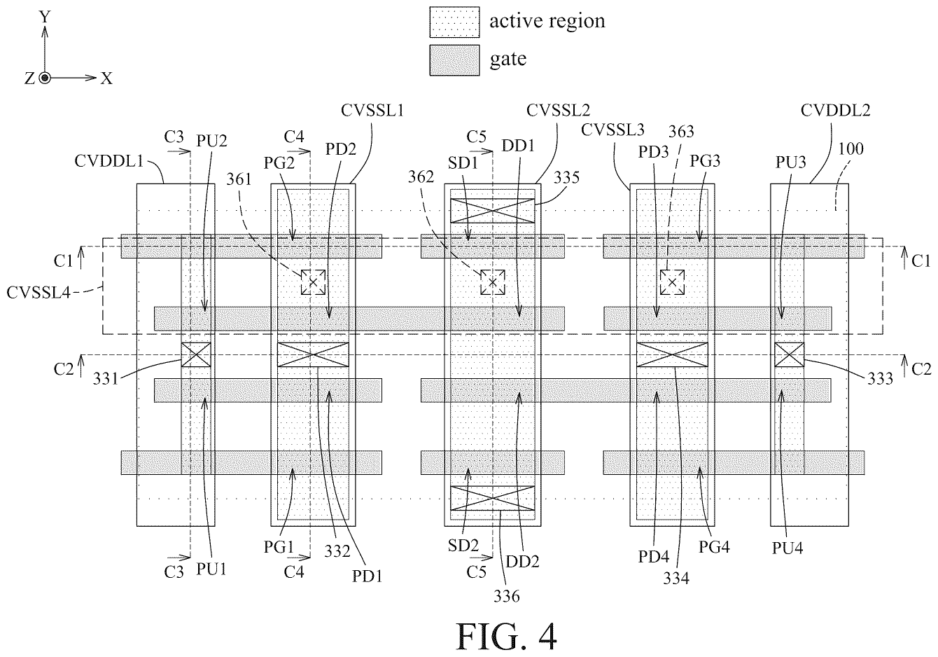

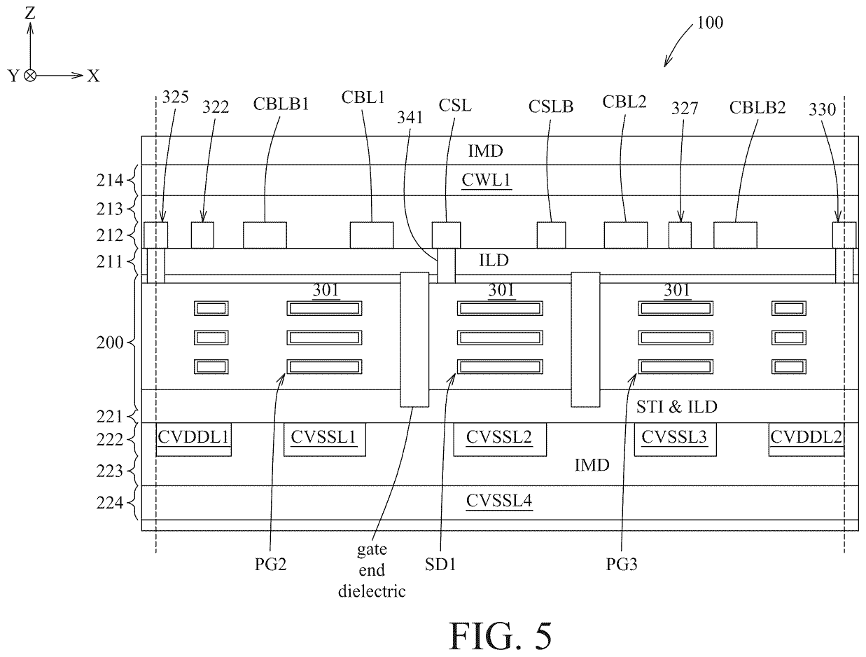

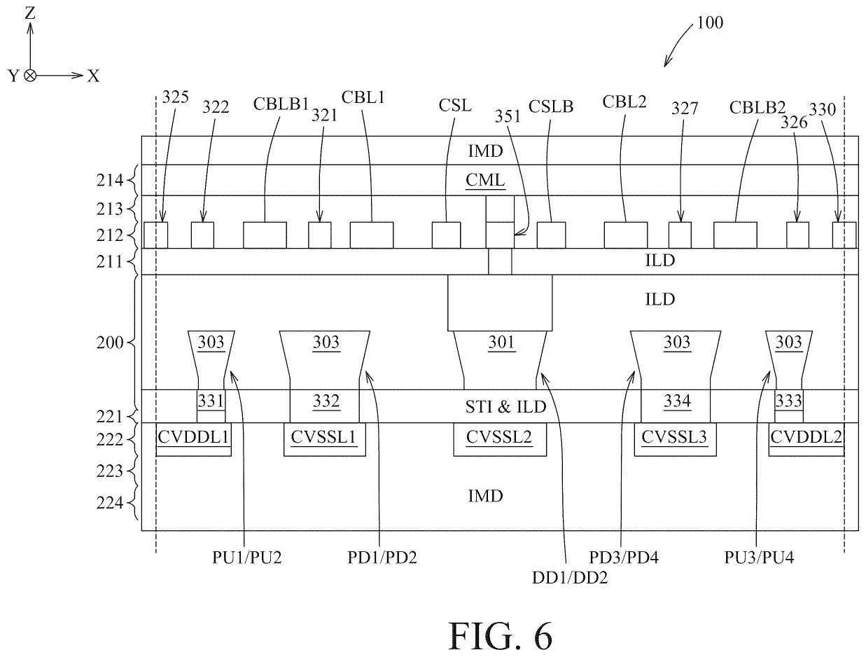

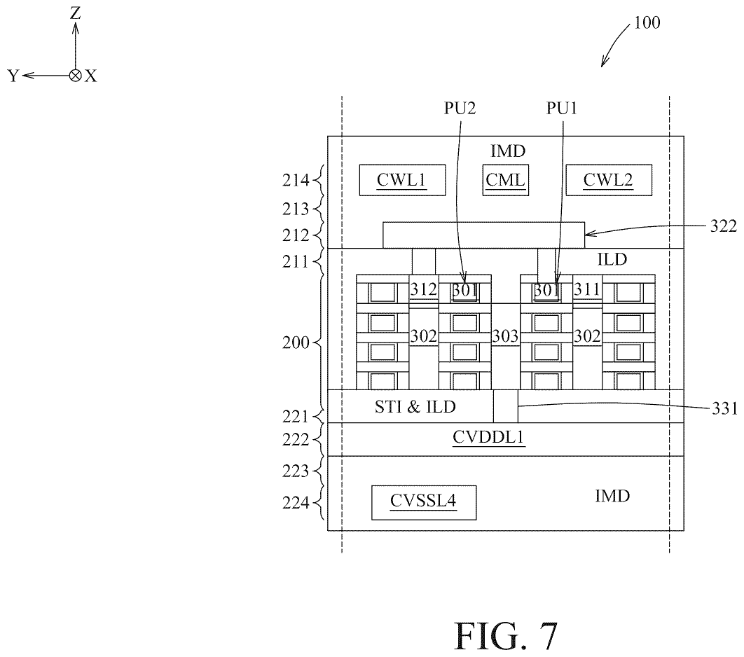

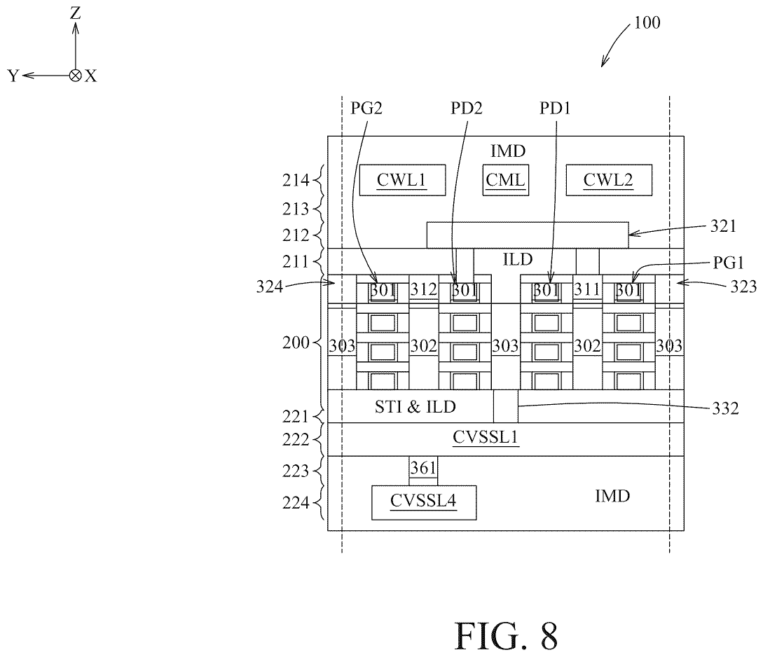

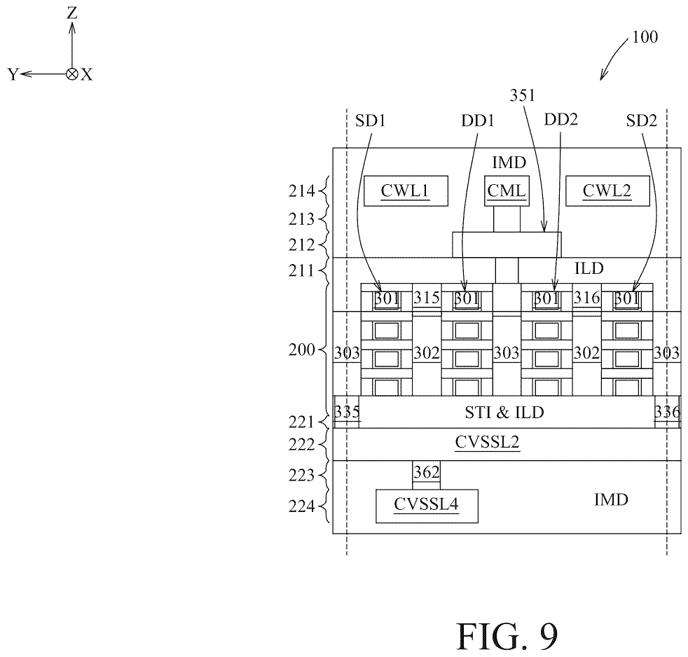

FIGS. 3 and 4 are schematic diagrams illustrating relative positions (in the X direction and the Y direction) of various components of a memory cell in accordance with some embodiments. FIGS. 5 to 9 are schematic sectional views of the memory cell respectively taken along lines C1-C1, C2-C2, C3-C3, C4-C4 and C5-C5 of FIGS. 3 and 4 in accordance with some embodiments. It should be noted that each of FIGS. 3 and 4 omits the depiction of some components of the memory cell for the sake of clarity.

Referring to FIGS. 3 to 9, with respect to each of the memory cells 100, the first storage portion 11, the second storage portion 12 and the match portion 13 are aligned in the X direction, with the match portion 13 disposed between the first storage portion 11 and the second storage portion 12. The first pull-up transistor (PU1), the second pull-up transistor (PU2), the third pull-up transistor (PU3), the fourth pull-up transistor (PU4), the first pull-down transistor (PD1), the second pull-down transistor (PD2), the third pull-down transistor (PD3), the fourth pull-down transistor (PD4), the first pass-gate transistor (PG1), the second pass-gate transistor (PG2), the third pass-gate transistor (PG3), the fourth pass-gate transistor (PG4), the first search transistor (SD1), the second search transistor (SD2), the first data transistor (DD1) and the second data transistor (DD2) are located in a transistor layer 200. The gate electrode of each of the transistors (PU1, PU2, PU3, PU4, PD1, PD2, PD3, PD4, PG1, PG2, PG3, PG4, SD1, SD2, DD1, DD2) extends in the X direction. The first source/drain regions and the second source/drain regions of the first pull-up transistor (PU1) and the second pull-up transistor (PU2) are formed in a first active region 51. The first source/drain regions and the second source/drain regions of the first pull-down transistor (PD1), the second pull-down transistor (PD2), the first pass-gate transistor (PG1) and the second pass-gate transistor (PG2) are formed in a second active region 52. The first source/drain regions and the second source/drain regions of the first search transistor (SD1), the second search transistor (SD2), the first data transistor (DD1) and the second data transistor (DD2) are formed in a third active region 53. The first source/drain regions and the second source/drain regions of the third pull-down transistor (PD3), the fourth pull-down transistor (PD4), the third pass-gate transistor (PG3) and the fourth pass-gate transistor (PG4) are formed in a fourth active region 54. The first source/drain regions and the second source/drain regions of the third pull-up transistor (PU3) and the fourth pull-up transistor (PU4) are formed in a fifth active region 55. The active regions 51-55 are aligned in the X direction, and each extend along the Y direction. The first active region 51 and the second active region 52 are adjacent to each other. The fourth active region 54 and the fifth active region 55 are adjacent to each other. The third active region 53 is disposed between the first active region 51 and the second active region 52 viewed collectively and the fourth active region 54 and the fifth active region 55 viewed collectively (e.g., the second active region 52 is disposed between the first active region 51 and the third active region 53, and the fourth active region 54 is disposed between the third active region 53 and the fifth active region 55). The first non-inverting bit line segment (CBL1), the first inverting bit line segment (CBLB1), the second non-inverting bit line segment (CBL2), the second inverting bit line segment (CBLB2), the non-inverting search line segment (CSL) and the inverting search line segment (CSLB) are located in a first front metal layer 212 stacked on the transistor layer 200, are aligned in the X direction, and each extend along the Y direction. The non-inverting search line segment (CSL) and the inverting search line segment (CSLB) are adjacent to each other. The first non-inverting bit line segment (CBL1) is disposed between the first inverting bit line segment (CBLB1) and the non-inverting search line segment (CSL). The second non-inverting bit line segment (CBL2) is disposed between the second inverting bit line segment (CBLB2) and the inverting search line segment (CSLB). The first word line segment (CWL1), the second word line segment (CWL2) and the match line segment (CML) are located in a second front metal layer 214 stacked on the first front metal layer 212, are aligned in the Y direction, and each extend along the X direction. The match line segment (CML) is disposed between the first word line segment (CWL1) and the second word line segment (CWL2). The first VDD line segment (CVDDL1), the second VDD line segment (CVDDL2), the first VSS line segment (CVSSL1), the second VSS line segment (CVSSL2) and the third VSS line segment (CVSSL3) are located in a first back metal layer 222 disposed below the transistor layer 200, are aligned in the X direction, and each extend along the Y direction. The first VSS line segment (CVSSL1) is disposed between the first VDD line segment (CVDDL1) and the second VSS line segment (CVSSL2). The third VSS line segment (CVSSL3) is disposed between the second VDD line segment (CVDDL2) and the second VSS line segment (CVSSL2). The fourth VSS line segment (CVSSL4) is located in a second back metal layer 224 disposed below the first back metal layer 222, and extends along the X direction.

With respect to each of the memory cells 100, the first source/drain region 302 of the first pass-gate transistor (PG1) and the first source/drain region 302 of the first pull-down transistor (PD1) share the same region (i.e., the first pass-gate transistor (PG1) and the first pull-down transistor (PD1) have a common first source/drain region 302). The common first source/drain region 302 of the first pass-gate transistor (PG1) and the first pull-down transistor (PD1) is connected to the first source/drain region 302 of the first pull-up transistor (PU1) through a front contact 311 that is located in an upper portion of the transistor layer 200. The front contact 311 is connected to the gate electrode 301 of the second pull-down transistor (PD2) through an interconnect element 321 that includes two front vias located in a bottom front via layer 211 disposed between the first front metal 212 and the transistor layer 200, and a front landing pad located in the first front metal layer 212. The gate electrode 301 of the second pull-down transistor (PD2) and the gate electrode 301 of the second pull-up transistor (PU2) are connected in series. Accordingly, the electrical connection among the first source/drain region 302 of the first pass-gate transistor (PG1), the first source/drain region 302 of the first pull-down transistor (PD1), the first source/drain region 302 of the first pull-up transistor (PU1), the gate electrode 301 of the second pull-down transistor (PD2) and the gate electrode 301 of the second pull-up transistor (PU2) is established. The first source/drain region 302 of the second pass-gate transistor (PG2) and the first source/drain region 302 of the second pull-down transistor (PD2) share the same region (i.e., the second pass-gate transistor (PG2) and the second pull-down transistor (PD2) have a common first source/drain region 302). The common first source/drain region 302 of the second pass-gate transistor (PG2) and the second pull-down transistor (PD2) is connected to the first source/drain region 302 of the second pull-up transistor (PU2) through a front contact 312 that is located in the upper portion of the transistor layer 200. The front contact 312 is connected to the gate electrode 301 of the first pull-up transistor (PU1) through an interconnect element 322 that includes two front vias located in the bottom front via layer 211, and a front landing pad located in the first front metal layer 212. The gate electrode 301 of the second pull-up transistor (PU2) and the gate electrode 301 of the second pull-down transistor (PD2) are connected in series. Accordingly, the electrical connection among the first source/drain region 302 of the second pass-gate transistor (PG2), the first source/drain region 302 of the second pull-down transistor (PD2), the first source/drain region 302 of the second pull-up transistor (PU2), the gate electrode 301 of the first pull-up transistor (PU1) and the gate electrode 301 of the first pull-down transistor (PD1) is established. The second source/drain region 303 of the first pull-up transistor (PU1) and the second source/drain region 303 of the second pull-up transistor (PU2) share the same region (i.e., the first pull-up transistor (PU1) and the second pull-up transistor (PU2) have a common second source/drain region 303). The common second source/drain region 303 of the first pull-up transistor (PU1) and the second pull-up transistor (PU2) is electrically connected to the first VDD line segment (CVDDL1) through a back contact 331 that is located in a lower portion of the transistor layer 200 and in a top back via layer 221 disposed between the transistor layer 200 and the first back metal layer 222. The second source/drain region 303 of the first pull-down transistor (PD1) and the second source/drain region 303 of the second pull-down transistor (PD2) share the same region (i.e., the first pull-down transistor (PD1) and the second pull-down transistor (PD2) have a common second source/drain region 303). The common second source/drain region 303 of the first pull-down transistor (PD1) and the second pull-down transistor (PD2) is electrically connected to the first VSS line segment (CVSSL1) through a back contact 332 that is located in the lower portion of the transistor layer 200 and in the top back via layer 221. The second source/drain region 303 of the first pass-gate transistor (PG1) is electrically connected to the first non-inverting bit line segment (CBL1) through an interconnect element 323 that includes a front contact located in the upper portion of the transistor layer 200, and a front via located in the bottom front via layer 211. The second source/drain region 303 of the second pass-gate transistor (PG2) is electrically connected to the first inverting bit line segment (CBLB1) through an interconnect element 324 that includes a front contact located in the upper portion of the transistor layer 200, and a front via located in the bottom front via layer 211. The gate electrode 301 of the first pass-gate transistor (PG1) and the gate electrode 301 of the second pass-gate transistor (PG2) are electrically connected to the first word line segment (CWL1) through an interconnect element 325 that includes two front vias located in the bottom front via layer 211, a front landing pad located in the first front metal layer 212, and another front via located in a first front via layer 213 disposed between the second front metal layer 214 and the first front metal layer 212.

Similarly, with respect to each of the memory cells 100, the first source/drain region of the third pass-gate transistor (PG3) and the first source/drain region of the third pull-down transistor (PD3) share the same region (i.e., the third pass-gate transistor (PG3) and the third pull-down transistor (PD3) have a common first source/drain region). The common first source/drain region of the third pass-gate transistor (PG3) and the third pull-down transistor (PD3) is connected to the first source/drain region of the third pull-up transistor (PU3) through a front contact 314 that is located in the upper portion of the transistor layer 200. The front contact 314 is connected to the gate electrode of the fourth pull-down transistor (PD4) through an interconnect element 327 that includes two front vias located in the bottom front via layer 211, and a front landing pad located in the first front metal layer 212. The gate electrode of the fourth pull-down transistor (PD4) and the gate electrode of the fourth pull-up transistor (PU4) are connected in series. Accordingly, the electrical connection among the first source/drain region of the third pass-gate transistor (PG3), the first source/drain region of the third pull-down transistor (PD3), the first source/drain region of the third pull-up transistor (PU3), the gate electrode of the fourth pull-down transistor (PD4) and the gate electrode of the fourth pull-up transistor (PU4) is established. The first source/drain region of the fourth pass-gate transistor (PG4) and the first source/drain region of the fourth pull-down transistor (PD4) share the same region (i.e., the fourth pass-gate transistor (PG4) and the fourth pull-down transistor (PD4) have a common first source/drain region). The common first source/drain region of the fourth pass-gate transistor (PG4) and the fourth pull-down transistor (PD4) is connected to the first source/drain region of the fourth pull-up transistor (PU4) through a front contact 313 that is located in the upper portion of the transistor layer 200. The front contact 313 is connected to the gate electrode of the third pull-up transistor (PU3) through an interconnect element 326 that includes two front vias located in the bottom front via layer 211, and a front landing pad located in the first front metal layer 212. The gate electrode of the third pull-up transistor (PU3) and the gate electrode of the third pull-down transistor (PD3) are connected in series. Accordingly, the electrical connection among the first source/drain region of the fourth pass-gate transistor (PG4), the first source/drain region of the fourth pull-down transistor (PD4), the first source/drain region of the fourth pull-up transistor (PU4), the gate electrode of the third pull-up transistor (PU3) and the gate electrode of the third pull-down transistor (PD3) is established. The second source/drain region 303 of the third pull-up transistor (PU3) and the second source/drain region 303 of the fourth pull-up transistor (PU4) share the same region (i.e., the third pull-up transistor (PU3) and the fourth pull-up transistor (PU4) have a common second source/drain region 303). The common second source/drain region 303 of the third pull-up transistor (PU3) and the fourth pull-up transistor (PU4) is electrically connected to the second VDD line segment (CVDDL2) through a back contact 333 that is located in the lower portion of the transistor layer 200 and in the top back via layer 221. The second source/drain region 303 of the third pull-down transistor (PD3) and the second source/drain region 303 of the fourth pull-down transistor (PD4) share the same region (i.e., the third pull-down transistor (PD3) and the fourth pull-down transistor (PD4) have a common second source/drain region 303). The common second source/drain region 303 of the third pull-down transistor (PD3) and the fourth pull-down transistor (PD4) is electrically connected to the third VSS line segment (CVSSL3) through a back contact 334 that is located in the lower portion of the transistor layer 200 and in the top back via layer 221. The second source/drain region of the third pass-gate transistor (PG3) is electrically connected to the second non-inverting bit line segment (CBL2) through an interconnect element 329 that includes a front contact located in the upper portion of the transistor layer 200, and a front via located in the bottom front via layer 211. The second source/drain region of the fourth pass-gate transistor (PG4) is electrically connected to the second inverting bit line segment (CBLB2) through an interconnect element 328 that includes a front contact located in the upper portion of the transistor layer 200, and a front via located in the bottom front via layer 211. The gate electrode of the third pass-gate transistor (PG3) and the gate electrode 301 of the fourth pass-gate transistor (PG4) are electrically connected to the second word line segment (CWL2) through an interconnect element 330 that includes two front vias located in the bottom front via layer 211, a front landing pad located in the first front metal layer 212, and another front via located in the first front via layer 213.

With respect to each of the memory cells 100, the first source/drain region 302 of the first search transistor (SD1) and the first source/drain region 302 of the first data transistor (DD1) share the same region (i.e., the first search transistor (SD1) and the first data transistor (DD1) have a common first source/drain region 302), so as to establish the electrical connection between the first source/drain region 302 of the first search transistor (SD1) and the first source/drain region 302 of the first data transistor (DD1). A front contact 315 located in the upper portion of the transistor layer 200 is disposed on and connected to the common first source/drain region 302 of the first search transistor (SD1) and the first data transistor (DD1), so as to reduce the resistance of the electrical connection between the first source/drain region 302 of the first search transistor (SD1) and the first source/drain region 302 of the first data transistor (DD1). The first source/drain region 302 of the second search transistor (SD2) and the first source/drain region 302 of the second data transistor (DD2) share the same region (i.e., the second search transistor (SD2) and the second data transistor (DD2) have a common first source/drain region 302), so as to establish the electrical connection between the first source/drain region 302 of the second search transistor (SD2) and the first source/drain region 302 of the second data transistor (DD2). A front contact 316 located in the upper portion of the transistor layer 200 is disposed on and connected to the common first source/drain region 302 of the second search transistor (SD2) and the second data transistor (DD2), so as to reduce the resistance of the electrical connection between the first source/drain region 302 of the second search transistor (SD2) and the first source/drain region 302 of the second data transistor (DD2). The gate electrode 301 of the first search transistor (SD1) is electrically connected to the non-inverting search line segment (CSL) through a front via 341 that is located in the bottom front via layer 211. The gate electrode 301 of the second search transistor (SD2) is electrically connected to the inverting search line segment (CSLB) through a front via 342 that is located in the bottom front via layer 211. The gate electrode 301 of the first data transistor (DD1) and the gate electrode 301 of the second pull-down transistor (PD2) are connected in series, so as to establish the electrical connection between the gate electrode 301 of the first data transistor (DD1) and the front contact 311 that serves as the non-inverting data node (D) of the first data latch (DL1) (see FIG. 2). The gate electrode 301 of the second data transistor (DD2) and the gate electrode of the fourth pull-down transistor (PD4) are connected in series, so as to establish the electrical connection between the gate electrode 301 of the second data transistor (DD2) and the front contact 314 that serves as the non-inverting data node (D) of the second data latch (DL2) (see FIG. 2). The second source/drain region 303 of the first search transistor (SD1) is electrically connected to the second VSS line segment (CVSSL2) through a back contact 335 that is located in the lower portion of the transistor layer 200 and in the top back via layer 221. The second source/drain region 303 of the second search transistor (SD2) is electrically connected to the second VSS line segment (CVSSL2) through a back contact 336 that is located in the lower portion of the transistor layer 200 and in the top back via layer 221. The second source/drain region 303 of the first data transistor (DD1) and the second source/drain region 303 of the second data transistor (DD2) share the same region (i.e., the first data transistor (DD1) and the second data transistor (DD2) have a common second source/drain region 303). The common second source/drain region 303 of the first data transistor (DD1) and the second data transistor (DD2) is electrically connected to the match line segment (CML) through an interconnect element 351 that includes a front contact located in the upper portion of the transistor layer 200, a front via located in the bottom front via layer 211, a front landing pad located in the first front metal layer 212, and another front via located in the front via layer 213. Accordingly, the electrical connection among the second source/drain region 303 of the first data transistor (DD1), the second source/drain region 303 of the second data transistor (DD2) and the match line segment (CML) is established.

With respect to each of the memory cells 100, the fourth VSS line segment (CVSSL4) is electrically connected to the first VSS line segment (CVSSL1) through a back via 361 that is located in a first back via layer 223 disposed between the first back metal layer 222 and the second back metal layer 224, is electrically connected to the second VSS line segment (CVSSL2) through a back via 362 that is located in the first back via layer 223, and is electrically connected to the third VSS line segment (CVSSL3) through a back via 363 that is located in the first back via layer 223.

In some embodiments, each of the transistors (PU1, PU2, PU3, PU4, PD1, PD2, PD3, PD4, PG1, PG2, PG3, PG4, SD1, SD2, DD1, DD2) of each of the memory cells 100 may be a planar field effect transistor (planar FET), a three-dimensional field effect transistor (3D FET) such as a fin field effect transistor (FinFET), a nanosheet gate-all-around field effect transistor (GAAFET), a nanowire GAAFET, a forksheet field effect transistor, a complementary field effect transistor (CFET), or other suitable FETs. FIGS. 5 to 9 depict an example where each of the transistors (PU1, PU2, PU3, PU4, PD1, PD2, PD3, PD4, PG1, PG2, PG3, PG4, SD1, SD2, DD1, DD2) of each of the memory cells 100 is a nanosheet GAAFET, each of the transistors (PU1, PU2, PU3, PU4) of each of the memory cells 100 has a p-type conductivity, and each of the transistors (PD1, PD2, PD3, PD4, PG1, PG2, PG3, PG4, SD1, SD2, DD1, DD2) of each of the memory cells 100 has an n-type conductivity.

Referring to FIGS. 1 and 3 to 9, with respect to each of the rows 101: the first word line segments (CWL1) of any two adjacent ones of the memory cells 100 in the row 101 are in contact with each other, so the first word line segments (CWL1) of the memory cells 100 in the row 101 cooperatively form the first word line (WL1) that corresponds to the row 101; the second word line segments (CWL2) of any two adjacent ones of the memory cells 100 in the row 101 are in contact with each other, so the second word line segments (CWL2) of the memory cells 100 in the row 101 cooperatively form the second word line (WL2) that corresponds to the row 101; the match line segments (CML) of any two adjacent ones of the memory cells 100 in the row 101 are in contact with each other, so the match line segments (CML) of the memory cells 100 in the row 101 cooperatively form the match line (ML) that corresponds to the row 101; and the fourth VSS line segments (CVSSL4) of any two adjacent ones of the memory cells 100 in the row 101 are in contact with each other, so the fourth VSS line segments (CVSSL4) of the memory cells 100 in the row 101 cooperatively form a fourth VSS line that corresponds to the row 101.

With respect to each of the columns 102: the first non-inverting bit line segments (CBL1) of any two adjacent ones of the memory cells 100 in the column 102 are in contact with each other, so the first non-inverting bit line segments (CBL1) of the memory cells 100 in the column 102 cooperatively form the first non-inverting bit line (BL1) that corresponds to the column 102; the first inverting bit line segments (CBLB1) of any two adjacent ones of the memory cells 100 in the column 102 are in contact with each other, so the first inverting bit line segments (CBLB1) of the memory cells 100 in the column 102 cooperatively form the first inverting bit line (BLB1) that corresponds to the column 102; the second non-inverting bit line segments (CBL2) of any two adjacent ones of the memory cells 100 in the column 102 are in contact with each other, so the second non-inverting bit line segments (CBL2) of the memory cells 100 in the column 102 cooperatively form the second non-inverting bit line (BL2) that corresponds to the column 102; the second inverting bit line segments (CBLB2) of any two adjacent ones of the memory cells 100 in the column 102 are in contact with each other, so the second inverting bit line segments (CBLB2) of the memory cells 100 in the column 102 cooperatively form the second inverting bit line (BLB2) that corresponds to the column 102; the non-inverting search line segments (CSL) of any two adjacent ones of the memory cells 100 in the column 102 are in contact with each other, so the non-inverting search line segments (CSL) of the memory cells 100 in the column 102 cooperatively form the non-inverting search line (SL) that corresponds to the column 102; the inverting search line segments (CSLB) of any two adjacent ones of the memory cells 100 in the column 102 are in contact with each other, so the inverting search line segments (CSLB) of the memory cells 100 in the column 102 cooperatively form the inverting search line (SLB) that corresponds to the column 102; the first VDD line segments (CVDDL1) of any two adjacent ones of the memory cells 100 in the column 102 are in contact with each other, so the first VDD line segments (CVDDL1) of the memory cells 100 in the column 102 cooperatively form a first VDD line that corresponds to the column 102 and that is for transmitting a first supply voltage; the second VDD line segments (CVDDL2) of any two adjacent ones of the memory cells 100 in the column 102 are in contact with each other, so the second VDD line segments (CVDDL2) of the memory cells 100 in the column 102 cooperatively form a second VDD line that corresponds to the column 102 and that is for transmitting the first supply voltage; the first VSS line segments (CVSSL1) of any two adjacent ones of the memory cells 100 in the column 102 are in contact with each other, so the first VSS line segments (CVSSL1) of the memory cells 100 in the column 102 cooperatively form a first VSS line that corresponds to the column 102 and that is for transmitting a second supply voltage lower than the first supply voltage in magnitude; the second VSS line segments (CVSSL2) of any two adjacent ones of the memory cells 100 in the column 102 are in contact with each other, so the second VSS line segments (CVSSL2) of the memory cells 100 in the column 102 cooperatively form a second VSS line that corresponds to the column 102 and that is for transmitting the second supply voltage; and the third VSS line segments (CVSSL3) of any two adjacent ones of the memory cells 100 in the column 102 are in contact with each other, so the third VSS line segments (CVSSL3) of the memory cells 100 in the column 102 cooperatively form a third VSS line that corresponds to the column 102 and that is for transmitting the second supply voltage.

By virtue of the fourth VSS lines (respectively corresponding to the rows 101) electrically connecting the first VSS lines (respectively corresponding to the columns 102), the second VSS lines (respectively corresponding to the columns 102) and the third VSS lines (respectively corresponding to the columns 102) in parallel, a line resistance (in the Y direction) from a combination of the first VSS lines, the second VSS lines and the third VSS lines can be reduced, thereby reducing a voltage drop caused by the combination of the first VSS lines, the second VSS lines and the third VSS lines, reducing power consumption of the memory device, and increasing a maximum operating speed of the memory device.

In a cell region of each of the memory cells 100, the first front metal layer 212 is free of any power line segment (i.e., free of the first VDD line segment (CVDDL1), the second VDD line segment (CVDDL2), the first VSS line segment (CVSSL1), the second VSS line segment (CVSSL2) and the third VSS line segment (CVSSL3)). This can facilitate shrinking of the memory device, and can enhance manufacturing capability of the memory device. In addition, the first front metal layer 212 can have more space for disposition of the first non-inverting bit line segment (CBL1), the first inverting bit line segment (CBLB1), the second non-inverting bit line segment (CBL2) and the second inverting bit line segment (CBLB2), and each of the first non-inverting bit line segment (CBL1), the first inverting bit line segment (CBLB1), the second non-inverting bit line segment (CBL2) and the second inverting bit line segment (CBLB2) can be made wider so as to have a low line resistance (in the Y direction). Therefore, the first non-inverting bit lines (BL1) that respectively correspond to the columns 102, the first inverting bit lines (BLB1) that respectively correspond to the columns 102, the second non-inverting bit lines (BL2) that respectively correspond to the columns 102, and the second inverting bit lines (BLB2) that respectively correspond to the columns 102 can each have a low line resistance (in the Y direction), and will thus contribute to only a low resistance-capacitance (RC) time delay. This is beneficial to increasing the maximum operating speed of the memory device and reducing a minimum write voltage of the memory device.

In the cell region of each of the memory cells 100, since the second front metal layer 214 only includes the first word line segment (CWL1), the second word line segment (CWL2) and the match line segment (CML), each of the first word line segment (CWL1) and the second word line segment (CWL2) can be made wider so as to have a low line resistance (in the X direction). Therefore, the first word lines (WL1) that respectively correspond to the rows 101, and the second word lines (WL2) that respectively correspond to the rows 101 can each have a low line resistance (in the X direction), and can thus cause a low RC time delay. This is beneficial to increasing the maximum operating speed of the memory device.

In the cell region of each of the memory cells 100, five active regions (including the first active region 51, the second active region 52, the third active region 53, the fourth active region 54 and the fifth active region 55) are required. This can facilitate the shrinking of the memory device, and can enhance the ability to manufacture the memory device.

By virtue of each of the memory cells 100 having a highly symmetric layout, component mismatch can be reduced, thereby enhancing ease of manufacturing the memory device.

Since each of the memory cells 100 is controlled by two bit line pairs (one of which includes the corresponding first non-inverting bit line (BL1) and the corresponding first inverting bit line (BLB1), and the other one of which includes the corresponding second non-inverting bit line (BL2) and the corresponding second inverting bit line (BLB2)), the memory device can have a write bandwidth that is twice a write bandwidth of a memory device where each memory cell is controlled by a bit line pair.

In some embodiments, with respect to each of the memory cells 100, a dimension of the memory cell 100 in the Y direction may be substantially equal to 4×PG, where PG denotes a minimum pitch of the gate electrodes of the transistors (PU1, PU2, PU3, PU4, PD1, PD2, PD3, PD4, PG1, PG2, PG3, PG4, SD1, SD2, DD1, DD2). A pitch of components is defined as a dimension between two adjacent components (measured from the same locations, such as center to center, or left edge to left edge). The pitch may not be a constant, so the minimum pitch is defined and constrained in designing the memory device.

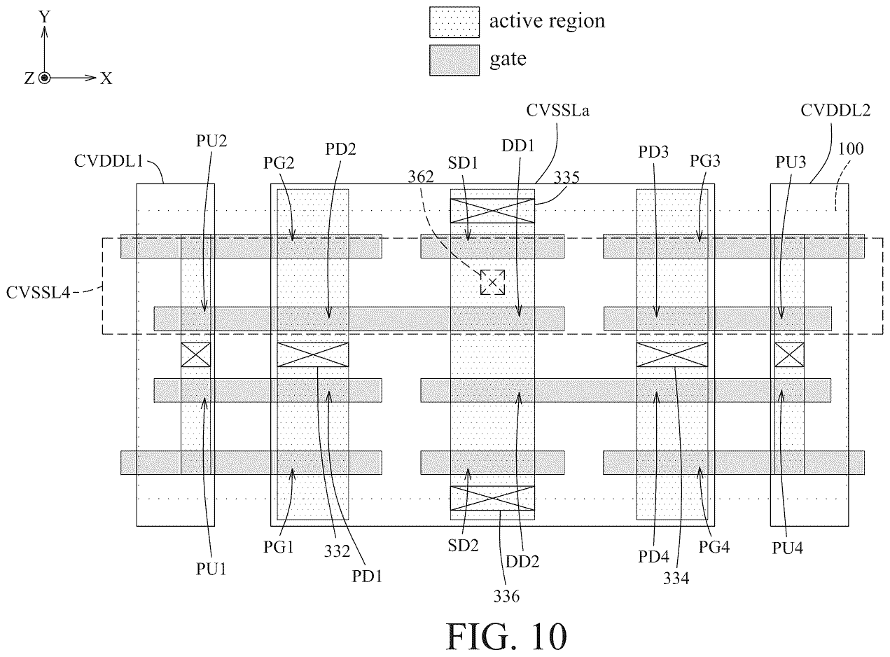

FIG. 10 is a schematic diagram illustrating relative positions (in the X direction and the Y direction) of various components of a memory cell in accordance with some embodiments. It should be noted that FIG. 10 omits the depiction of some components of the memory cell for the sake of clarity. Referring to FIGS. 1, 3 and 10, the memory device depicted in FIGS. 1, 3 and 10 is similar to the memory device described with reference to FIGS. 1 to 9, but differs therefrom in that the first VSS line segment (CVSSL1) (see FIG. 4), the second VSS line segment (CVSSL2) (see FIG. 4) and the third VSS line segment (CVSSL3) (see FIG. 4) of each of the memory cells 100 are replaced by a first VSS line segment (CVSSLa), and the back vias 361, 363 (see FIG. 4) of each of the memory cells 100 are deleted. With respect to each of the memory cells 100, the first VSS line segment (CVSSLa) is located in the first back metal layer 222 (see FIG. 5), extends in the Y direction, is disposed between the first VDD line segment (CVDDL1) and the second VDD line segment (CVDDL2), and has a width (in the X direction) larger than a sum of a width (in the X direction) of the first VSS line segment (CVSSL1) (see FIG. 4), a width (in the X direction) of the second VSS line segment (CVSSL2) (see FIG. 4) and a width (in the X direction) of the third VSS line segment (CVSSL3) (see FIG. 4). The first VSS line segment (CVSSLa) is electrically connected to the common second source/drain region of the first pull-down transistor (PD1) and the second pull-down transistor (PD2) through the back contact 332, is electrically connected to the common second source/drain region of the third pull-down transistor (PD3) and the fourth pull-down transistor (PD4) through the back contact 334, is electrically connected to the second source/drain region of the first search transistor (SD1) through the back contact 335, is electrically connected to the second source/drain region of the second search transistor (SD2) through the back contact 336, and is electrically connected to the fourth VSS line segment (CVSSL4) through the back via 362. With respect to each of the columns 102, the first VSS line segments (CVSSLa) of any two adjacent ones of the memory cells 100 in the column 102 are in contact with each other, and the first VSS line segments (CVSSLa) of the memory cells 100 in the column 102 cooperatively form a first VSS line that corresponds to the column 102 and that is for transmitting the second supply voltage. Therefore, a line resistance (in the Y direction) collectively from the first VSS lines that respectively correspond to the columns 102 can be reduced, thereby reducing a voltage drop caused by the first VSS lines. This reduces the power consumption of the memory device, and increases the maximum operating speed of the memory device.

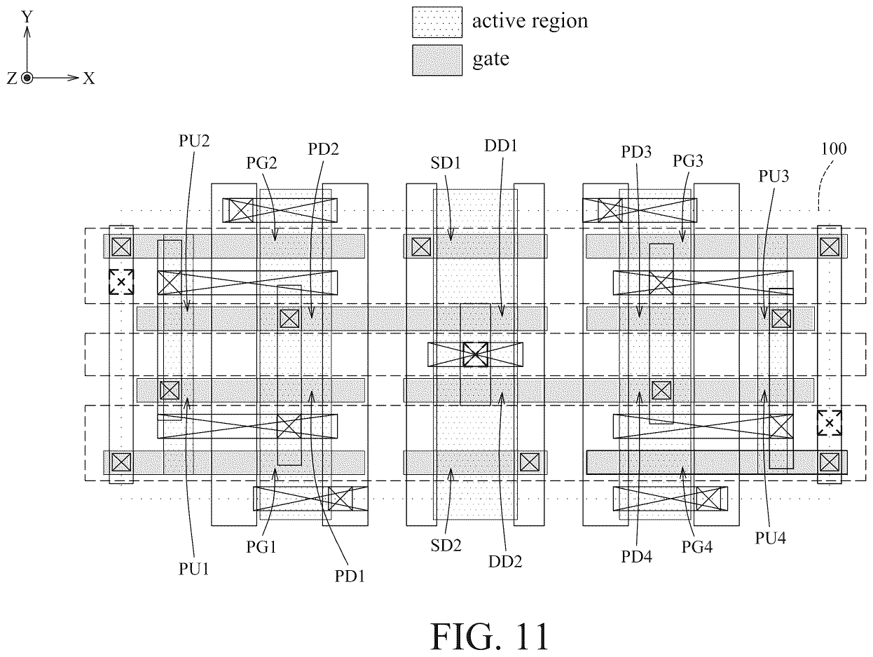

FIG. 11 is a schematic diagram illustrating relative positions (in the X direction and the Y direction) of various components of a memory cell in accordance with some embodiments. It should be noted that FIG. 11 omits the depiction of some components of the memory cell for the sake of clarity. Referring to FIGS. 1, 4 and 11, the memory device depicted in FIGS. 1, 4 and 11 is similar to the memory device described with reference to FIGS. 1 to 9, but differs therefrom in that the front contacts 315, 316 (see FIG. 3) of each of the memory cells 100 are deleted. Therefore, with respect to each of the memory cells 100, a parasitic capacitance of the electrical connection between the first source/drain region of the first search transistor (SD1) and the first source/drain region of the first data transistor (DD1) and a parasitic capacitance of the electrical connection between the first source/drain region of the second search transistor (SD2) and the first source/drain region of the second data transistor (DD2) can be reduced.

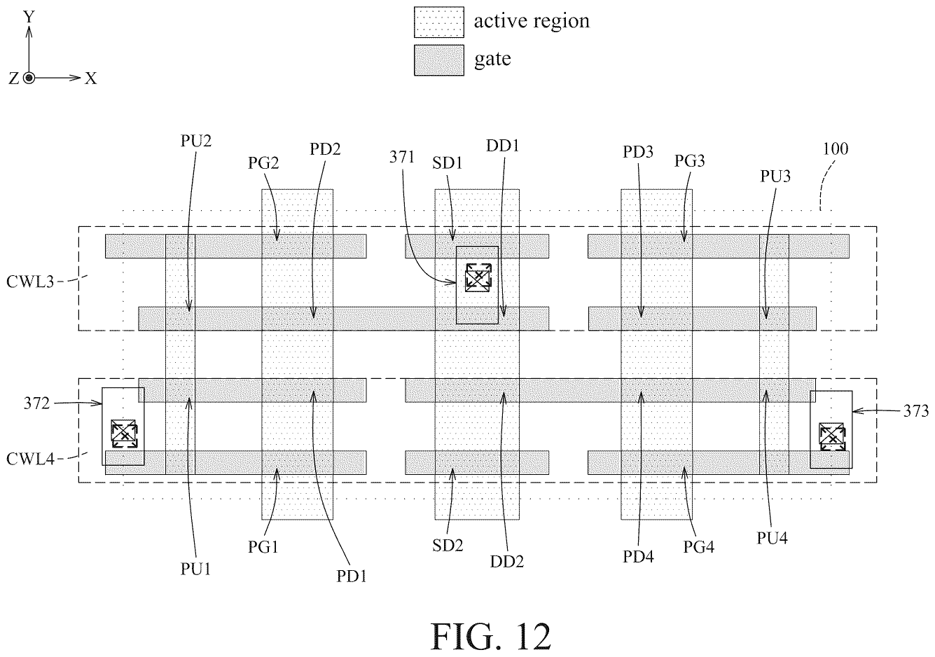

FIG. 12 is a schematic diagram illustrating relative positions (in the X direction and the Y direction) of various components of a memory cell in accordance with some embodiments. It should be noted that FIG. 12 omits the depiction of some components of the memory cell for the sake of clarity. Referring to FIGS. 1, 3, 4 and 12, the memory device depicted in FIGS. 1, 3, 4 and 12 is similar to the memory device described with reference to FIGS. 1 to 9, but differs therefrom in that each of the memory cells 100 further includes a third word line segment (CWL3) and a fourth word line segment (CWL4). With respect to each of the memory cells 100, the third word line segment (CWL3) and the fourth word line segment (CWL4) are located in an additional front metal layer stacked on the second front metal layer 214, are aligned in the Y direction, and each extend along the X direction. The third word line segment (CWL3) is electrically connected to the first word line segment (CWL1). The fourth word line segment (CWL4) is electrically connected to the second word line segment (CWL2). With respect to each of the rows 101, the third word line segments (CWL3) of any two adjacent ones of the memory cells 100 in the row 101 are in contact with each other, the third word line segments (CWL3) of the memory cells 100 in the row 101 cooperate with the first word line segments (CWL1) of the memory cells 100 in the row 101 to form the first word line (WL1) that corresponds to the row 101, the fourth word line segments (CWL4) of any two adjacent ones of the memory cells 100 in the row 101 are in contact with each other, and the fourth word line segments (CWL4) of the memory cells 100 in the row 101 cooperate with the second word line segments (CWL2) of the memory cells 100 in the row 101 to form the second word line (WL2) that corresponds to the row 101. FIGS. 3, 4 and 12 depict an example where, with respect to each of the memory cells 100: the third word line segment (CWL3) and the fourth word line segment (CWL4) are located in a fourth front metal layer (not shown); the third word line segment (CWL3) is electrically connected to the first word line segment (CWL1) through an interconnect element 371 that includes a front via located in a third front via layer (disposed between the fourth front metal layer and the second front metal layer 214 (see FIG. 5)) (not shown), a front landing pad located in a third front metal layer (disposed between the third front via layer and the second front metal layer 214 (see FIG. 5)) (not shown), and another front via located in a second front via layer (disposed between the third front metal layer and the second front metal layer 214 (see FIG. 5)) (not shown); and the fourth word line segment (CWL4) is electrically connected to the second word line segment (CWL2) through two interconnect elements 372, 373, each of which includes a front via located in the third front via layer (not shown), a front landing pad located in the third front metal layer (not shown), and another front via located in the second front via layer (not shown). In another example, with respect to each of the memory cells 100, the third word line segment (CWL3) and the fourth word line segment (CWL4) may be located in the third front metal layer, the third word line segment (CWL3) may be electrically connected to the first word line segment (CWL1) through a front via that is located in the second front via layer, and the fourth word line segment (CWL4) may be electrically connected to the second word line segment (CWL2) through two front vias that are located in the second front via layer. Therefore, the first word lines (WL1) that respectively correspond to the rows 101 and the second word lines (WL2) that respectively correspond to the rows 101 can each have a low line resistance (in the X direction), and can thus cause a low RC time delay. This is beneficial to increasing the maximum operating speed of the memory device.

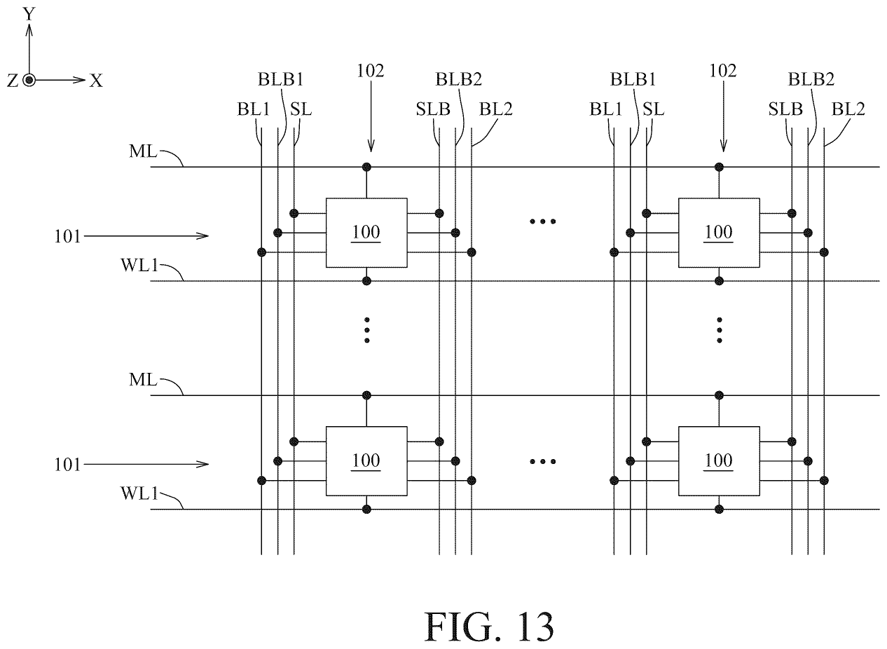

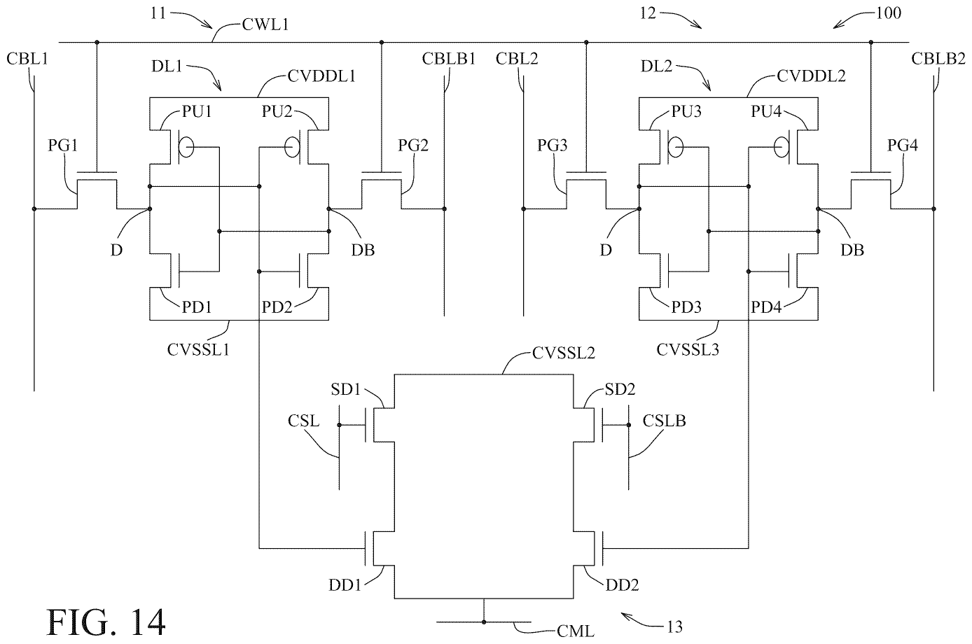

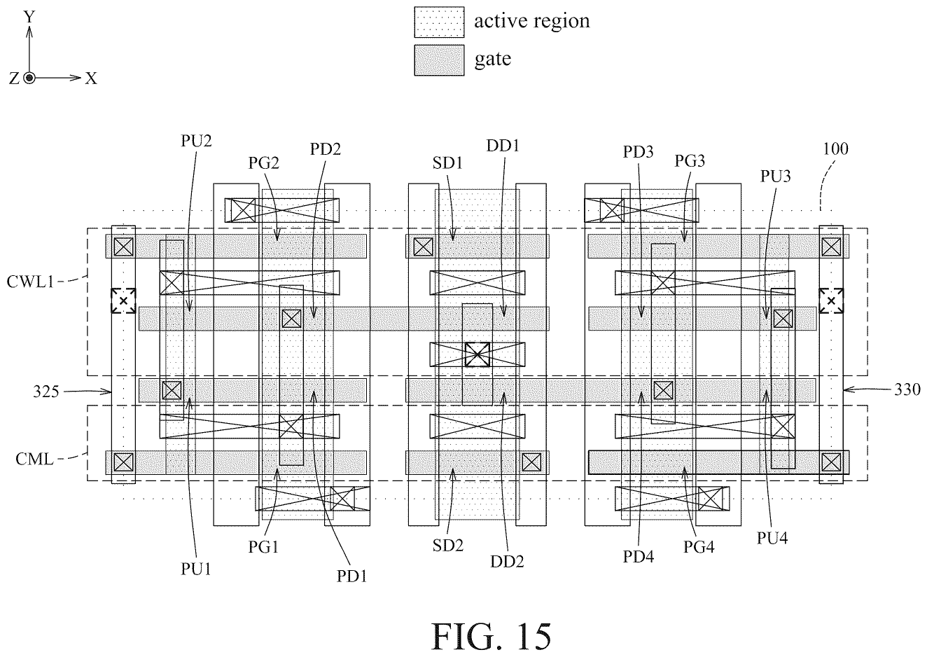

FIG. 13 is a block diagram illustrating a memory device in accordance with some embodiments. FIG. 14 is a circuit diagram illustrating a memory cell in accordance with some embodiments. FIG. 15 is a schematic diagram illustrating relative positions (in the X direction and the Y direction) of various components of a memory cell in accordance with some embodiments. It should be noted that FIG. 15 omits the depiction of some components of the memory cell for the sake of clarity. Referring to FIGS. 4 and 13 to 15, the memory device depicted in FIGS. 4 and 13 to 15 is similar to the memory device described with reference to FIGS. 1 to 9, but differs therefrom in that, with respect to each of the memory cells 100, the second word line segment (CWL2) (see FIG. 3) is deleted, and the gate electrode of the third pass-gate transistor (PG3) and the gate electrode of the fourth pass-gate transistor (PG4) are electrically connected to the first word line segment (CWL1) through the interconnect element 330. That is, the second word lines (WL2) (see FIG. 1) that respectively correspond to the rows 101 are deleted.

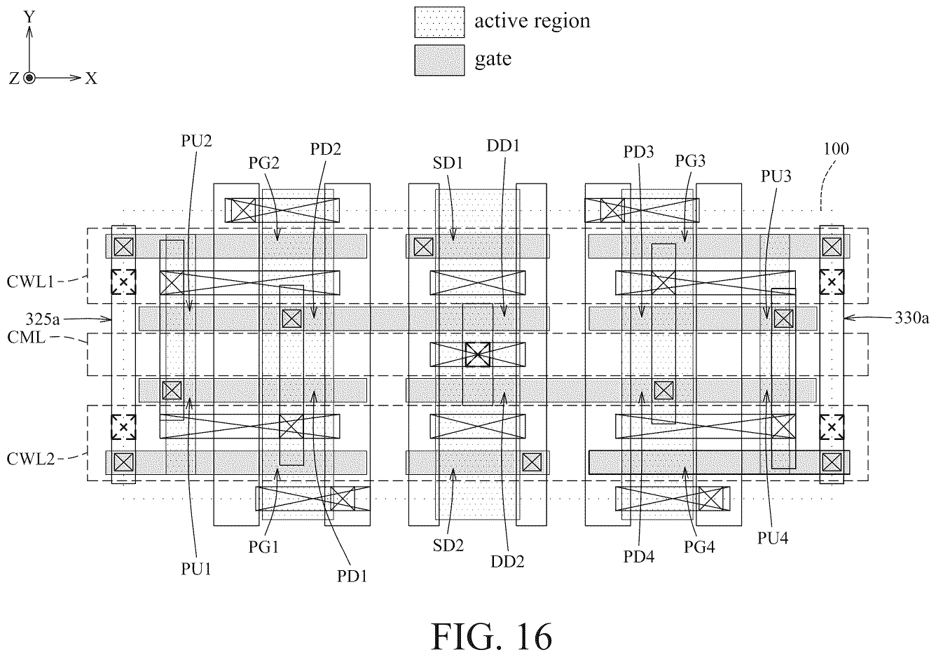

FIG. 16 is a schematic diagram illustrating relative positions (in the X direction and the Y direction) of various components of a memory cell in accordance with some embodiments. It should be noted that FIG. 16 omits the depiction of some components of the memory cell for the sake of clarity. Referring to FIGS. 4, 13 and 16, the memory device depicted in FIGS. 4, 13 and 16 is similar to the memory device depicted in FIGS. 4, 13 and 15, but differs therefrom in that each of the memory cells 100 further includes a second word line segment (CWL2). The second word line segment (CWL2) is located in the second front metal layer 214 (see FIG. 5), and extends along the X direction. The second word line segment (CWL2) is electrically connected to the gate electrode of the first pass-gate transistor (PG1), the gate electrode of the second pass-gate transistor (PG2) and the first word line segment (CWL1) through an interconnect element (325a) that includes two front vias located in the bottom front via layer 211 (see FIG. 5), a front landing pad located in the first front metal layer 212 (see FIG. 5), and another two front vias located in the first front via layer 213 (see FIG. 5). The second word line segment (CWL2) is further electrically connected to the gate electrode of the third pass-gate transistor (PG3), the gate electrode of the fourth pass-gate transistor (PG4) and the first word line segment (CWL1) through an interconnect element (330a) that includes two front vias located in the bottom front via layer 211 (see FIG. 5), a front landing pad located in the first front metal layer 212 (see FIG. 5), and another two front vias located in the first front via layer 213 (see FIG. 5).

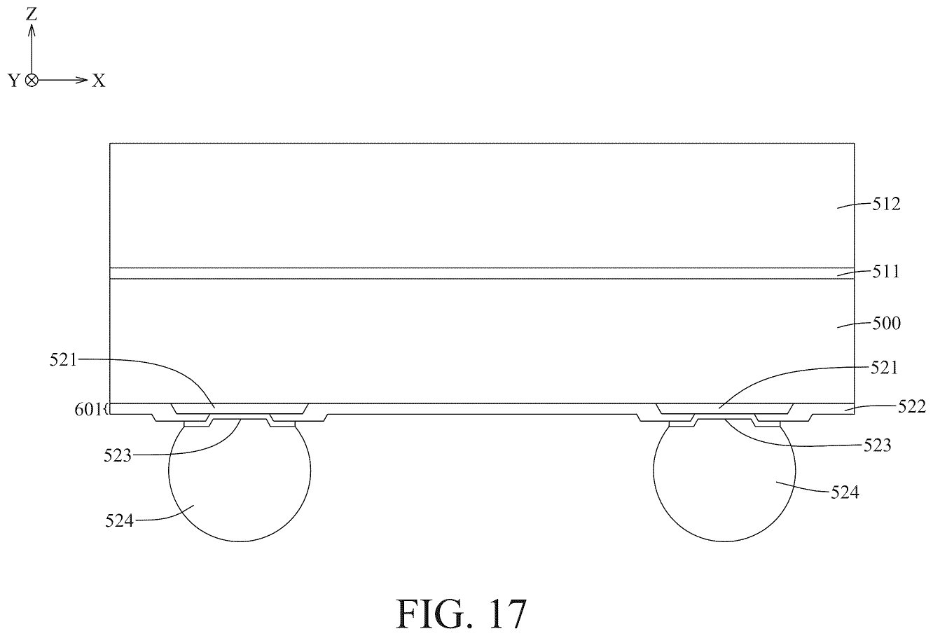

FIG. 17 is a schematic sectional view of a memory device in accordance with some embodiments. Referring to FIG. 17, the memory device includes a memory feature 500, a dielectric layer 511, a blank substrate 512, a plurality of bump pads 521, a passivation layer 522, a plurality of under bump metallurgy (UBM) films 523 and a plurality of bump balls 524. The memory feature 500 has a structure as depicted in FIGS. 1, 3 and 4. The dielectric layer 511 is disposed on an upper surface of the memory feature 500. The blank substrate 512 (e.g., a silicon substrate) is disposed on an upper surface of the dielectric layer 511. The bump pads 521 are disposed on a lower surface of the memory feature 500. The passivation layer 522 covers a portion of the lower surface of the memory feature 500 that is not covered by the bump pads 521 and also covers an outer portion of a lower surface of each of the bump pads 521, and exposes an inner portion of the lower surface of each of the bump pads 521. Each of the UBM films 523 covers at least the inner portion of the lower surface of a respective one of the bump pads 521. Each of the bump balls 524 is disposed on a lower surface of a respective one of the UBM films 523.

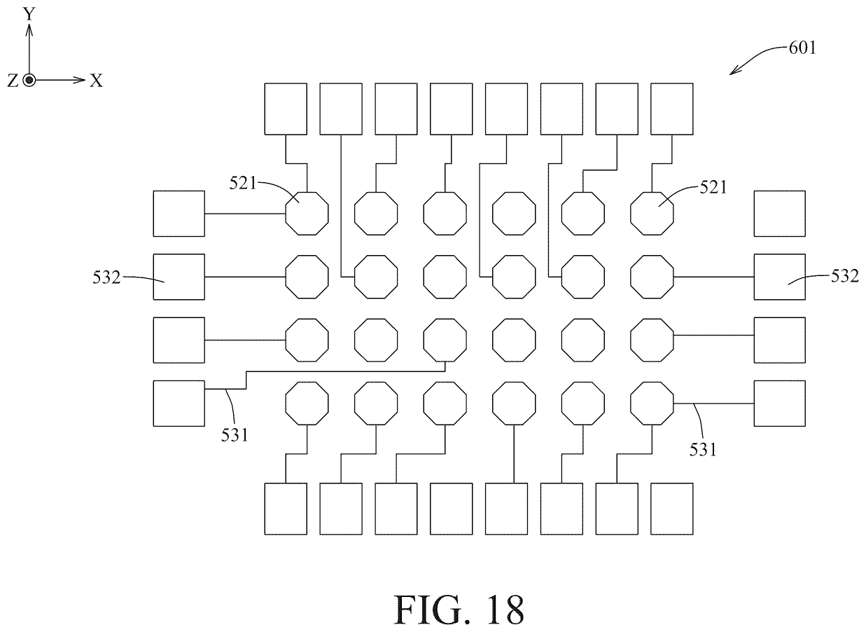

FIG. 18 is a top view of a bump pad layer in accordance with some embodiments. Referring to FIGS. 17 and 18, the bump pad layer 601 is disposed on and located below the memory feature 500, and the bump pads 521 are located in the bump pad layer 601. In addition to the bump pads 521, the bump pad layer 601 may further include a plurality of metal lines 531 and a plurality of test pads 532. Each of the bump pads 521 may be electrically connected to a power line (e.g., a VDD line or a VSS line) or a signal line of the memory feature 500 through an interconnect element that is disposed right above the bump pad 521, or through one of the metal lines 531 and an interconnect element that is disposed above and offset from the bump pad 521. Each of the bump pads 521 may be further electrically connected to one of the test pads 532 through one of the metal lines 531.

In accordance with some embodiments of the present disclosure, a memory cell includes a first storage portion, a second storage portion, a match portion, a first non-inverting bit line segment, a first inverting bit line segment, a second non-inverting bit line segment, a second inverting bit line segment, a non-inverting search line segment, an inverting search line segment, a first word line segment, a match line segment, a first VDD line segment and a first VSS line segment. The first storage portion, the second storage portion and the match portion are located in a transistor layer, and are aligned in a first direction, where the match portion is disposed between the first storage portion and the second storage portion. The first non-inverting bit line segment, the first inverting bit line segment, the second non-inverting bit line segment, the second inverting bit line segment, the non-inverting search line segment and the inverting search line segment are located in a first front metal layer stacked on the transistor layer, and each extend along a second direction, where the first non-inverting bit line segment and the first inverting bit line segment are electrically connected to the first storage portion, the second non-inverting bit line segment and the second inverting bit line segment are electrically connected to the second storage portion, and the non-inverting search line segment and the inverting search line segment are electrically connected to the match portion. The first word line segment and the match line segment are located in a second front metal layer stacked on the first front metal layer, and each extend along the first direction, where the first word line segment is electrically connected to the first storage portion, and the match line segment is electrically connected to the match portion. The first VDD line segment and the first VSS line segment are located in a first back metal layer disposed below the transistor layer, each extend along the second direction, and are electrically connected to the first storage portion.

In accordance with some embodiments of the present disclosure, the first storage portion includes a first data latch, a first pass-gate transistor and a second pass-gate transistor. The first data latch includes a non-inverting data node and an inverting data node. The first pass-gate transistor includes a gate electrode that is electrically connected to the first word line segment, a first source/drain region that is electrically connected to the non-inverting data node of the first data latch, and a second source/drain region that is electrically connected to the first non-inverting bit line segment. The second pass-gate transistor includes a gate electrode that is electrically connected to the first word line segment, a first source/drain region that is electrically connected to the inverting data node of the first data latch, and a second source/drain region that is electrically connected to the first inverting bit line segment.

In accordance with some embodiments of the present disclosure, the second storage portion includes a second data latch, a third pass-gate transistor and a fourth pass-gate transistor. The second data latch includes a non-inverting data node and an inverting data node. The third pass-gate transistor includes a gate electrode, a first source/drain region that is electrically connected to the non-inverting data node of the second data latch, and a second source/drain region that is electrically connected to the second non-inverting bit line segment. The fourth pass-gate transistor includes a gate electrode, a first source/drain region that is electrically connected to the inverting data node of the second data latch, and a second source/drain region that is electrically connected to the second inverting bit line segment.

In accordance with some embodiments of the present disclosure, the match portion includes a first search transistor, a second search transistor, a first data transistor and a second data transistor. The first search transistor includes a gate electrode that is electrically connected to the non-inverting search line segment, a first source/drain region and a second source/drain region. The second search transistor includes a gate electrode that is electrically connected to the inverting search line segment, a first source/drain region and a second source/drain region. The first data transistor includes a gate electrode that is electrically connected to the non-inverting data node of the first data latch, a first source/drain region that is electrically connected to the first source/drain region of the first search transistor, and a second source/drain region that is electrically connected to the match line segment. The second data transistor includes a gate electrode that is electrically connected to the non-inverting data node of the second data latch, a first source/drain region that is electrically connected to the first source/drain region of the second search transistor, and a second source/drain region that is electrically connected to the match line segment.

In accordance with some embodiments of the present disclosure, each of the first storage portion, the second storage portion and the match portion includes a plurality of transistors. Some of the plurality of transistors of the first storage portion are formed in a first active region, and the other ones of the plurality of transistors of the first storage portion are formed in a second active region. The plurality of transistors of the match portion are formed in a third active region. Some of the plurality of transistors of the second storage portion are formed in a fourth active region, and the other ones of the plurality of transistors of the second storage portion are formed in a fifth active region. The first active region, the second active region, the third active region, the fourth active region and the fifth active region are aligned in the first direction, and each extend along the second direction, where the first active region and the second active region are adjacent to each other, the fourth active region and the fifth active region are adjacent to each other, and the third active region is disposed between the first active region and the second active region viewed collectively and the fourth active region and the fifth active region viewed collectively.

In accordance with some embodiments of the present disclosure, the memory cell further includes a second word line segment. The second word line segment is located in the second front metal layer, extends along the first direction, and is electrically connected to the second storage portion.

In accordance with some embodiments of the present disclosure, the memory cell further includes a third word line segment and a fourth word line segment. The third word line segment and the fourth word line segment are located in an additional front metal layer stacked on the second front metal layer, and each extend along the first direction, where the third word line segment is electrically connected to the first word line segment, and the fourth word line segment is electrically connected to the second word line segment.

In accordance with some embodiments of the present disclosure, the first word line segment is further electrically connected to the second storage portion.

In accordance with some embodiments of the present disclosure, the memory cell further includes a second word line segment. The second word line segment is located in the second front metal layer, extends along the first direction, and is electrically connected to the first storage portion, the second storage portion and the first word line segment.

In accordance with some embodiments of the present disclosure, each of the first storage portion, the second storage portion and the match portion includes a plurality of transistors. Each of the plurality of transistors of the first storage portion, the second storage portion and the match portion includes a gate electrode extending along the first direction. The gate electrodes of the plurality of transistors of the first storage portion, the second storage portion and the match portion have a minimum pitch of PG. A dimension of the memory cell in the second direction is substantially equal to 4×PG.

In accordance with some embodiments of the present disclosure, the first VSS line segment is further electrically connected to the second storage portion and the match portion.

In accordance with some embodiments of the present disclosure, the memory cell further includes a second VSS line segment and a third VSS line segment. The second VSS line segment and the third VSS line segment are located in the first back metal layer, and each extend along the second direction, where the second VSS line segment is electrically connected to the match portion, and the third VSS line segment is electrically connected to the second storage portion.

In accordance with some embodiments of the present disclosure, the memory cell further includes a fourth VSS line segment. The fourth VSS line segment is located in a second back metal layer disposed below the first back metal layer, extends along the first direction, and is electrically connected to the first VSS line segment, the second VSS line segment and the third VSS line segment.

In accordance with some embodiments of the present disclosure, a memory cell includes a first storage portion, a second storage portion and a match portion which are located in a transistor layer, which are aligned in a first direction, and each of which includes a plurality of transistors. The match portion is disposed between the first storage portion and the second storage portion. Some of the plurality of transistors of the first storage portion are formed in a first active region, and the other ones of the plurality of transistors of the first storage portion are formed in a second active region. The plurality of transistors of the match portion are formed in a third active region. Some of the plurality of transistors of the second storage portion are formed in a fourth active region, and the other ones of the plurality of transistors of the second storage portion are formed in a fifth active region. The first active region, the second active region, the third active region, the fourth active region and the fifth active region are aligned in the first direction, and each extend along a second direction, with the first active region and the second active region adjacent to each other, the fourth active region and the fifth active region adjacent to each other, and the third active region disposed between the first active region and the second active region viewed collectively and the fourth active region and the fifth active region viewed collectively.

In accordance with some embodiments of the present disclosure, the memory cell further includes a first non-inverting bit line segment, a first inverting bit line segment, a second non-inverting bit line segment, a second inverting bit line segment, a non-inverting search line segment and an inverting search line segment. The first non-inverting bit line segment, the first inverting bit line segment, the second non-inverting bit line segment, the second inverting bit line segment, the non-inverting search line segment and the inverting search line segment are located in a first front metal layer stacked on the transistor layer, and each extend along the second direction, where the first non-inverting bit line segment and the first inverting bit line segment are electrically connected to the first storage portion, the second non-inverting bit line segment and the second inverting bit line segment are electrically connected to the second storage portion, and the non-inverting search line segment and the inverting search line segment are electrically connected to the match portion.

In accordance with some embodiments of the present disclosure, the memory cell further includes a first word line segment and a match line segment. The first word line segment and the match line segment are located in a second front metal layer stacked on the first front metal layer, and each extend along the first direction, where the first word line segment is electrically connected to the first storage portion, and the match line is electrically connected to the match portion.

In accordance with some embodiments of the present disclosure, the memory cell further includes a first VDD line segment and a second VDD line segment. The first VDD line segment and the second VDD line segment are located in a first back metal layer disposed below the transistor layer, and each extend along the second direction, where the first VDD line segment is electrically connected to the first storage portion, and the second VDD line segment is electrically connected to the second storage portion.

In accordance with some embodiments of the present disclosure, a memory cell includes a first storage portion, a second storage portion and a match portion. The first storage portion includes a first pull-up transistor, a second pull-up transistor, a first pull-down transistor, a second pull-down transistor, a first pass-gate transistor and a second pass-gate transistor that are located in a transistor layer, where the first pull-up transistor, the second pull-up transistor, the first pull-down transistor and the second pull-down transistor cooperatively form a first data latch for storing data, and when the first pass-gate transistor and the second pass-gate transistor conduct, a write operation is allowed to be performed on the first data latch. The second storage portion includes a third pull-up transistor, a fourth pull-up transistor, a third pull-down transistor, a fourth pull-down transistor, a third pass-gate transistor and a fourth pass-gate transistor that are located in the transistor layer, where the third pull-up transistor, the fourth pull-up transistor, the third pull-down transistor and the fourth pull-down transistor cooperatively form a second data latch for storing data, and when the third pass-gate transistor and the fourth pass-gate transistor conduct, a write operation is allowed to be performed on the second data latch. The match portion includes a first search transistor, a second search transistor, a first data transistor and a second data transistor that are located in the transistor layer, and is configured to detect a match between data stored in the first data latch and the second data latch and data inputted to the match portion. The first pull-up transistor and the second pull-up transistor are formed in a first active region, and the first pull-down transistor, the second pull-down transistor, the first pass-gate transistor and the second pass-gate transistor are formed in a second active region. The first search transistor, the second search transistor, the first data transistor and the second data transistor are formed in a third active region. The third pull-down transistor, the fourth pull-down transistor, the third pass-gate transistor and the fourth pass-gate transistor are formed in a fourth active region, and the third pull-up transistor and the fourth pull-up transistor are formed in a fifth active region. The first active region, the second active region, the third active region, the fourth active region and the fifth active region are aligned in a first direction, and each extend along a second direction, with the second active region disposed between the first active region and the third active region, and the fourth active region disposed between the third active region and the fifth active region.

In accordance with some embodiments of the present disclosure, the memory cell further includes a first non-inverting bit line segment, a first inverting bit line segment, a second non-inverting bit line segment and a second inverting bit line segment. The first non-inverting bit line segment is electrically connected to the first pass-gate transistor. The first inverting bit line segment is electrically connected to the second pass-gate transistor. The second non-inverting bit line segment is electrically connected to the third pass-gate transistor. The second inverting bit line segment is electrically connected to the fourth pass-gate transistor.

In accordance with some embodiments of the present disclosure, the first non-inverting bit line segment, the first inverting bit line segment, the second non-inverting bit line segment and the second inverting bit line segment are located in a metal layer that is free of any power line segment.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory cell comprising:
a first storage portion, a second storage portion and a match portion which are located in a transistor layer, and which are aligned in a first direction, where the match portion is disposed between the first storage portion and the second storage portion;
a first non-inverting bit line segment, a first inverting bit line segment, a second non-inverting bit line segment, a second inverting bit line segment, a non-inverting search line segment and an inverting search line segment which are located in a first front metal layer stacked on the transistor layer, and each of which extends along a second direction, where the first non-inverting bit line segment and the first inverting bit line segment are electrically connected to the first storage portion, the second non-inverting bit line segment and the second inverting bit line segment are electrically connected to the second storage portion, and the non-inverting search line segment and the inverting search line segment are electrically connected to the match portion;
a first word line segment and a match line segment which are located in a second front metal layer stacked on the first front metal layer, and each of which extends along the first direction, where the first word line segment is electrically connected to the first storage portion, and the match line segment is electrically connected to the match portion; and
a first VDD line segment and a first VSS line segment which are located in a first back metal layer disposed below the transistor layer, each of which extends along the second direction, and which are electrically connected to the first storage portion.

2. The memory cell according to claim 1, wherein:
the first storage portion includes a first data latch, a first pass-gate transistor and a second pass-gate transistor;
the first data latch includes a non-inverting data node and an inverting data node;
the first pass-gate transistor includes a gate electrode that is electrically connected to the first word line segment, a first source/drain region that is electrically connected to the non-inverting data node of the first data latch, and a second source/drain region that is electrically connected to the first non-inverting bit line segment; and
the second pass-gate transistor includes a gate electrode that is electrically connected to the first word line segment, a first source/drain region that is electrically connected to the inverting data node of the first data latch, and a second source/drain region that is electrically connected to the first inverting bit line segment.

3. The memory cell according to claim 2, wherein:
the second storage portion includes a second data latch, a third pass-gate transistor and a fourth pass-gate transistor;
the second data latch includes a non-inverting data node and an inverting data node;
the third pass-gate transistor includes a gate electrode, a first source/drain region that is electrically connected to the non-inverting data node of the second data latch, and a second source/drain region that is electrically connected to the second non-inverting bit line segment; and
the fourth pass-gate transistor includes a gate electrode, a first source/drain region that is electrically connected to the inverting data node of the second data latch, and a second source/drain region that is electrically connected to the second inverting bit line segment.

4. The memory cell according to claim 3, wherein:
the match portion includes a first search transistor, a second search transistor, a first data transistor and a second data transistor;
the first search transistor includes a gate electrode that is electrically connected to the non-inverting search line segment, a first source/drain region and a second source/drain region;
the second search transistor includes a gate electrode that is electrically connected to the inverting search line segment, a first source/drain region and a second source/drain region;
the first data transistor includes a gate electrode that is electrically connected to the non-inverting data node of the first data latch, a first source/drain region that is electrically connected to the first source/drain region of the first search transistor, and a second source/drain region that is electrically connected to the match line segment; and
the second data transistor includes a gate electrode that is electrically connected to the non-inverting data node of the second data latch, a first source/drain region that is electrically connected to the first source/drain region of the second search transistor, and a second source/drain region that is electrically connected to the match line segment.

5. The memory cell according to claim 1, wherein:
each of the first storage portion, the second storage portion and the match portion includes a plurality of transistors;
some of the plurality of transistors of the first storage portion are formed in a first active region, and the other ones of the plurality of transistors of the first storage portion are formed in a second active region;
the plurality of transistors of the match portion are formed in a third active region;
some of the plurality of transistors of the second storage portion are formed in a fourth active region, and the other ones of the plurality of transistors of the second storage portion are formed in a fifth active region; and
the first active region, the second active region, the third active region, the fourth active region and the fifth active region are aligned in the first direction, and each extend along the second direction, where the first active region and the second active region are adjacent to each other, the fourth active region and the fifth active region are adjacent to each other, and the third active region is disposed between the first active region and the second active region viewed collectively and the fourth active region and the fifth active region viewed collectively.

6. The memory cell according to claim 1, further comprising:
a second word line segment located in the second front metal layer, extending along the first direction, and electrically connected to the second storage portion.

7. The memory cell according to claim 6, further comprising:
a third word line segment and a fourth word line segment which are located in an additional front metal layer stacked on the second front metal layer, and each of which extends along the first direction, where the third word line segment is electrically connected to the first word line segment, and the fourth word line segment is electrically connected to the second word line segment.

8. The memory cell according to claim 1, wherein:
the first word line segment is further electrically connected to the second storage portion.

9. The memory cell according to claim 8, further comprising:
a second word line segment located in the second front metal layer, extending along the first direction, and electrically connected to the first storage portion, the second storage portion and the first word line segment.

10. The memory cell according to claim 1, wherein:
each of the first storage portion, the second storage portion and the match portion includes a plurality of transistors;
each of the plurality of transistors of the first storage portion, the second storage portion and the match portion includes a gate electrode extending along the first direction;
the gate electrodes of the plurality of transistors of the first storage portion, the second storage portion and the match portion have a minimum pitch of PG; and
a dimension of the memory cell in the second direction is substantially equal to 4×PG.

11. The memory cell according to claim 1, wherein:
the first VSS line segment is further electrically connected to the second storage portion and the match portion.

12. The memory cell according to claim 1, further comprising:
a second VSS line segment and a third VSS line segment which are located in the first back metal layer, and each of which extends along the second direction, where the second VSS line segment is electrically connected to the match portion, and the third VSS line segment is electrically connected to the second storage portion.

13. The memory cell according to claim 12, further comprising:
a fourth VSS line segment located in a second back metal layer disposed below the first back metal layer, extending along the first direction, and electrically connected to the first VSS line segment, the second VSS line segment and the third VSS line segment.

14. A memory cell comprising:
a first storage portion, a second storage portion and a match portion which are located in a transistor layer, which are aligned in a first direction, and each of which includes a plurality of transistors;
wherein the match portion is disposed between the first storage portion and the second storage portion;
wherein some of the plurality of transistors of the first storage portion are formed in a first active region, and the other ones of the plurality of transistors of the first storage portion are formed in a second active region;
wherein the plurality of transistors of the match portion are formed in a third active region;
wherein some of the plurality of transistors of the second storage portion are formed in a fourth active region, and the other ones of the plurality of transistors of the second storage portion are formed in a fifth active region; and
wherein the first active region, the second active region, the third active region, the fourth active region and the fifth active region are aligned in the first direction, and each extend along a second direction, with the first active region and the second active region adjacent to each other, the fourth active region and the fifth active region adjacent to each other, and the third active region disposed between the first active region and the second active region viewed collectively and the fourth active region and the fifth active region viewed collectively.

15. The memory cell according to claim 14, further comprising:
a first non-inverting bit line segment, a first inverting bit line segment, a second non-inverting bit line segment, a second inverting bit line segment, a non-inverting search line segment and an inverting search line segment which are located in a first front metal layer stacked on the transistor layer, and each of which extends along the second direction, where the first non-inverting bit line segment and the first inverting bit line segment are electrically connected to the first storage portion, the second non-inverting bit line segment and the second inverting bit line segment are electrically connected to the second storage portion, and the non-inverting search line segment and the inverting search line segment are electrically connected to the match portion.

16. The memory cell according to claim 15, further comprising:
a first word line segment and a match line segment which are located in a second front metal layer stacked on the first front metal layer, and each of which extends along the first direction, where the first word line segment is electrically connected to the first storage portion, and the match line is electrically connected to the match portion.

17. The memory cell according to claim 15, further comprising:
a first VDD line segment and a second VDD line segment which are located in a first back metal layer disposed below the transistor layer, and each of which extends along the second direction, where the first VDD line segment is electrically connected to the first storage portion, and the second VDD line segment is electrically connected to the second storage portion.

18. A memory cell comprising:
a first storage portion including a first pull-up transistor, a second pull-up transistor, a first pull-down transistor, a second pull-down transistor, a first pass-gate transistor and a second pass-gate transistor that are located in a transistor layer, where the first pull-up transistor, the second pull-up transistor, the first pull-down transistor and the second pull-down transistor cooperatively form a first data latch for storing data, and when the first pass-gate transistor and the second pass-gate transistor conduct, a write operation is allowed to be performed on the first data latch;
a second storage portion including a third pull-up transistor, a fourth pull-up transistor, a third pull-down transistor, a fourth pull-down transistor, a third pass-gate transistor and a fourth pass-gate transistor that are located in the transistor layer, where the third pull-up transistor, the fourth pull-up transistor, the third pull-down transistor and the fourth pull-down transistor cooperatively form a second data latch for storing data, and when the third pass-gate transistor and the fourth pass-gate transistor conduct, a write operation is allowed to be performed on the second data latch;
a match portion including a first search transistor, a second search transistor, a first data transistor and a second data transistor that are located in the transistor layer, and configured to detect a match between data stored in the first data latch and the second data latch and data inputted to the match portion;
wherein the first pull-up transistor and the second pull-up transistor are formed in a first active region, and the first pull-down transistor, the second pull-down transistor, the first pass-gate transistor and the second pass-gate transistor are formed in a second active region;
wherein the first search transistor, the second search transistor, the first data transistor and the second data transistor are formed in a third active region;
wherein the third pull-down transistor, the fourth pull-down transistor, the third pass-gate transistor and the fourth pass-gate transistor are formed in a fourth active region, and the third pull-up transistor and the fourth pull-up transistor are formed in a fifth active region; and
wherein the first active region, the second active region, the third active region, the fourth active region and the fifth active region are aligned in a first direction, and each extend along a second direction, with the second active region disposed between the first active region and the third active region, and the fourth active region disposed between the third active region and the fifth active region.

19. The memory cell according to claim 18, further comprising:
a first non-inverting bit line segment electrically connected to the first pass-gate transistor;
a first inverting bit line segment electrically connected to the second pass-gate transistor;
a second non-inverting bit line segment electrically connected to the third pass-gate transistor; and
a second inverting bit line segment electrically connected to the fourth pass-gate transistor.

20. The memory cell according to claim 19, wherein:
the first non-inverting bit line segment, the first inverting bit line segment, the second non-inverting bit line segment and the second inverting bit line segment are located in a metal layer that is free of any power line segment.
